(19) United States
(12) Patent Application Publication
(10) Pub. No.: US 2008/0283935 A1
(43) Pub. Date: Nov. 20, 2008

(54) TRENCH ISOLATION STRUCTURE AND METHOD OF MANUFACTURE THEREFOR

(75) Inventors: Seetharaman Sridhar, Richardson, TX (US); Craig Hall, Lucas, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/750,713

(22) Filed: May 18, 2007

(51) Int. Cl. H01L 21/336; H01L 21/76; H01L 29/06; H01L 29/94

(52) U.S. Cl. 257/390; 257/622; 438/296; 438/429; 257/E29.345; 257/E29.005; 257/E21.409; 257/E21.54

(57) ABSTRACT

The disclosure provides a trench isolation structure, a semiconductor device, and a method for manufacturing a semiconductor device. The semiconductor device, in one embodiment, includes a substrate having a first device region and a second device region, wherein the first device region includes a first gate structure and first source/drain regions and the second device region includes a second gate structure and second source/drain regions. The semiconductor device further includes a trench isolation structure configured to isolate the first device region from the second device region, the trench isolation structure comprising: 1) an isolation trench located within the substrate, wherein the isolation trench includes an opening portion and a bulbous portion, and further wherein a maximum width of the opening portion is less than a maximum width of the bulbous portion, and 2) dielectric material substantially filling the isolation trench.

### TECHNICAL FIELD OF THE INVENTION

The invention is directed, in general, to a semiconductor device and, more specifically, to a semiconductor device including a trench isolation structure and method of manufacture therefor.

### BACKGROUND OF THE INVENTION

Semiconductor devices are used in many electronic applications. One type of semiconductor device is a transistor. Manufacturers of transistors are continually reducing the size of transistors to increase their performance and to manufacture electronic devices in smaller sizes.

When many transistors are manufactured on a single integrated circuit die, oftentimes leakage current increases and breakdown voltage decreases, which severely degrades transistor performance. Manufacturers of transistors use isolation methods between transistors and other semiconductor devices to address these problems and others. Shallow Trench Isolation (“STI”) is one method used for isolating transistors and other semiconductor devices. However, as transistor geometry shrinks, STI falls short of providing adequate isolation.

Accordingly, what is needed in the art is a new isolation structure and method of manufacture therefore that accommodates the aforementioned problems.

### SUMMARY OF THE INVENTION

To address the above-discussed deficiencies of the prior art, the disclosure provides a trench isolation structure, a semiconductor device, and a method for manufacturing a semiconductor device. The semiconductor device, in one embodiment, includes a substrate having a first device region and a second device region, wherein the first device region includes a first gate structure and first source/drain regions and the second device region includes a second gate structure and second source/drain regions. The semiconductor device further includes a trench isolation structure configured to isolate the first device region from the second device region, the trench isolation structure comprising: 1) an isolation trench located within the substrate, wherein the isolation trench includes an opening portion and a bulbous portion, and further wherein a maximum width of the opening portion is less than a maximum width of the bulbous portion, and 2) dielectric material substantially filling the isolation trench.

Additionally provided is a trench isolation structure. The trench isolation structure, without limitation, includes a isolation trench located within a substrate, wherein the isolation trench is configured such that a ratio of an opening width of the isolation trench to a base width of the isolation trench is less than about 1:1.1. The trench isolation structure further includes dielectric material substantially filling the isolation trench.

Further provided is the method for manufacturing the semiconductor device. This method for manufacture, among others, may include: 1) forming a substrate having a first device region and a second device region, 2) forming a trench isolation structure configured to isolate the first device region from the second device region, including: forming an isolation trench within the substrate, wherein the isolation trench includes an opening portion and a bulbous portion, and further wherein a maximum width of the opening portion is less than a maximum width of the bulbous portion, and substantially filling the isolation trench with dielectric material, 3) forming a first gate structure and first source/drain regions in the first device region, and 4) forming a second gate structure and second source/drain regions in the second device region.

Additionally provided is a method for manufacturing a trench isolation structure. This method, in one embodiment, includes forming an isolation trench within a substrate, wherein the isolation trench is configured such that a ratio of an opening width of the isolation trench to a base width of the isolation trench is less than about 1:1.1, and substantially filling the isolation trench with dielectric material.

### BRIEF DESCRIPTION OF THE DRAWINGS

For a more complete understanding of the invention, reference is now made to the following descriptions taken in conjunction with the accompanying drawings, in which:

FIGS. 1A and 1B illustrate a semiconductor device manufactured in accordance with an example embodiment;

FIGS. 2A-2E illustrate various different configurations for a trench isolation structure manufactured in accordance with this disclosure;

FIGS. 3-7 illustrate detailed steps of one example embodiment for manufacturing a trench isolation structure in accordance with this disclosure; and

FIG. 8 illustrates an integrated circuit (IC) having been manufactured using one embodiment of the disclosure.

### DETAILED DESCRIPTION

The present disclosure is based, at least in part, on the recognition that as semiconductor feature sizes continue to decrease current leakage is becoming more problematic. More specifically, the present disclosure recognizes that as trench isolation structures (e.g., shallow trench isolation (STI) structures) continue to decrease in size the current leakage is becoming a significant issue. Without being limited to such, the present disclosure believes that the increased current leakage issue is due in part to the inability to accurately align the N-well region and P-well region under the ever decreasing trench isolation structures. For instance, present trench isolation structures have widths of less than about 60 nm, with about 30 nm being allotted to each of the N-well region and P-well region. However, the alignment accuracy is only about 25 nm, leaving only about a 5 nm alignment tolerance. Thus, in those instances wherein the alignment is off by 5 nm or more, there is a possibility that the N-well region or P-well region might not even contact the trench isolation structure. Such a circumstance is catastrophic. Based upon the foregoing, as well as significant experimentation, the present disclosure acknowledges that by making an opening width of the trench isolation structure less than another width of the trench isolation structure, an increased alignment tolerance may be obtained.

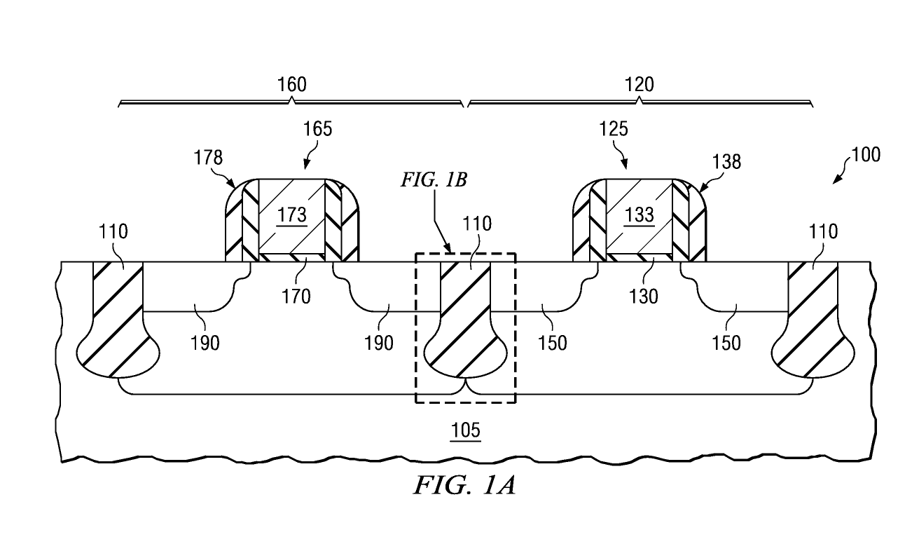

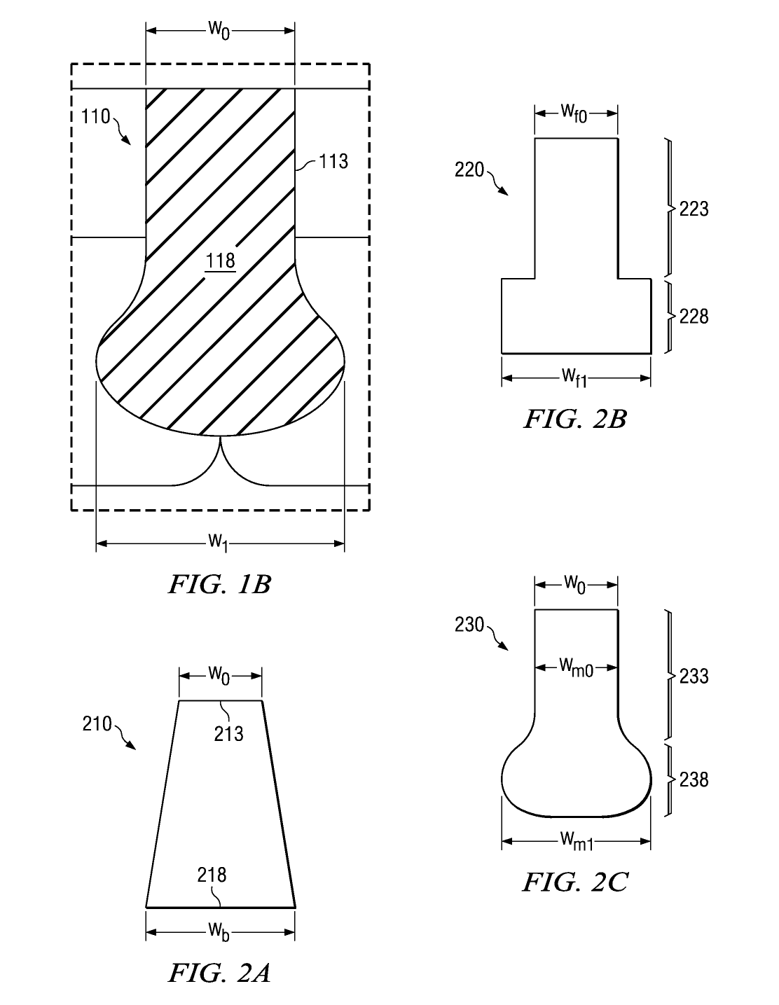

FIGS. 1A and 1B illustrate a semiconductor device 100 manufactured in accordance with an example embodiment. The semiconductor device 100 includes a substrate 105. Located within the substrate 105 are trench isolation structures 110. The trench isolation structures 110 each include a trench 113 and dielectric material 118 substantially filling the trench 113.

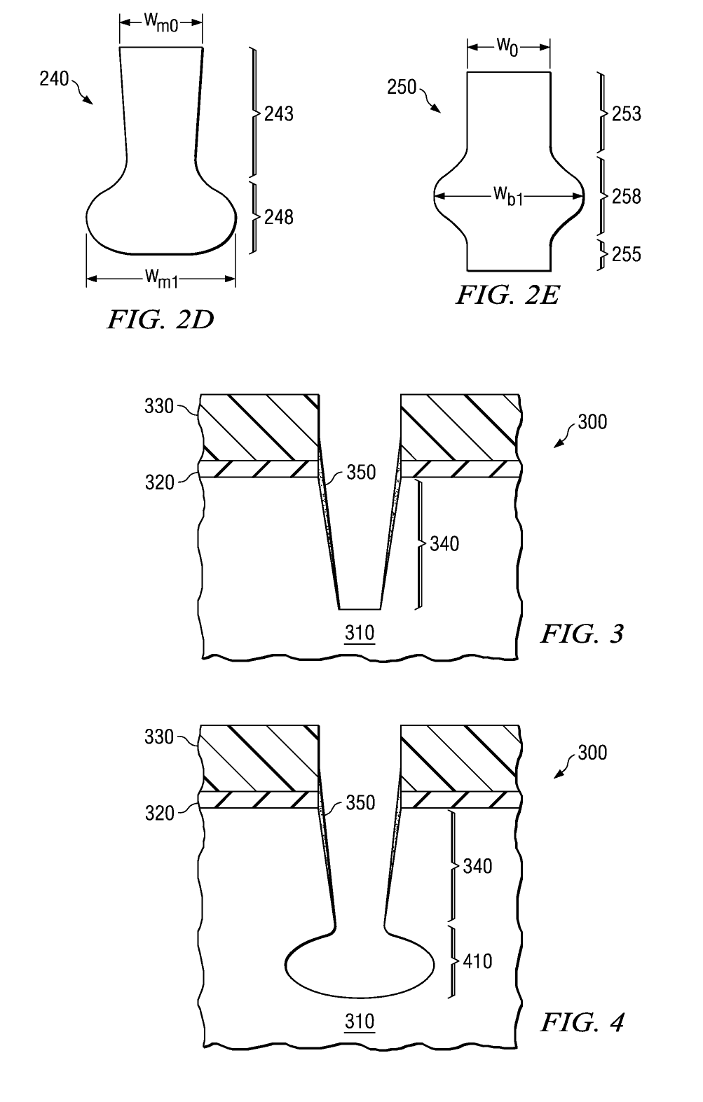

In the example embodiment of FIGS. 1A and 1B, the trench 113 includes an opening width (w₀) and another width (w₁), wherein the opening width (w₀) is less than the other width (w₁) In the embodiment of FIGS. 1A and 1B, the other width (w₁) is a base width; however, other embodiments exist wherein the other width (w₁) is an intermediate width or other width. Any one of a number of trench configurations may accommodate the aforementioned width requirement. More detail regarding these configurations may be found in FIGS. 2A-2E discussed below. Nevertheless, those configurations wherein the sidewalls of the trench are completely vertical, or those configurations wherein the width of the trench successively decreases from the opening of the trench to the base of the trench, do not meet the aforementioned requirement.

The substrate 105 of FIG. 1A further includes a PMOS device region 120 and an NMOS device region 160. In the example embodiment of FIG. 1A, the trench isolation structures 110 help define the boundaries of the PMOS device region 120 and the NMOS device region 160. In one embodiment, an interface of the PMOS device region 120 and an interface of the NMOS device region 160 contact one another at a midpoint of one of the trench isolation structures 110.

The PMOS device region 120 of FIG. 1A includes a first gate structure 125 located over the substrate 105. The first gate structure 125, in this embodiment, includes a first gate dielectric 130, a first gate electrode 133, and source/drain spacers 138. The first gate dielectric 130, first gate electrode 133, and source/drain spacers 138 may comprise many different materials, conventional and not, and remain within the scope of this disclosure. The first gate dielectric 130, first gate electrode 133, and source/drain spacers 138 may additionally be formed using conventional processes. The PMOS device region 120 further includes first source/drain regions 150 located on opposing sides of the first gate structure 125. The first source/drain regions 150, in the embodiment of FIG. 1, include first extension implants and first source/drain implants.

The substrate 110 further includes the NMOS device region 160. The NMOS device region 160 includes a second gate structure 165 located over the substrate 110. The second gate structure 165, in this embodiment, includes a second gate dielectric 170, a second gate electrode 173, and source/drain spacers 178. Similar to above, the second gate dielectric 170, second gate electrode 173, and source/drain spacers 178 may comprise many different materials, conventional and not, and may be formed using many different processes, conventional and not. The NMOS device region 160 further includes second source/drain regions 190 located on opposing sides of the second gate structure 165. Each of the second source/drain regions 190, at least in the example embodiment of FIG. 1A, further includes second extension implants and second source/drain implants.

FIGS. 2A-2E illustrate various different configurations for a trench isolation structure manufactured in accordance with this disclosure. FIG. 2A illustrates a trench isolation structure 210. The trench isolation structure 210 includes an opening 213 and a base 218. In this embodiment, the opening 213 has an opening width (w₀) and the base 218 has a base width (w_{b}), wherein the opening width (w₀) is less than the base width (w_{b}) For example, in one embodiment a ratio of the opening width (w₀) of the isolation trench to a base width (w_{b}) of the isolation trench is less than about 1:1.1. In an alternative embodiment, the ratio is less than about 1:1.2. In the particular embodiment of FIG. 2A, a width of the trench isolation structure 210 successively decreases from the opening 213 to the base 218.

FIG. 2B illustrates a trench isolation structure 220. The trench isolation structure 220 includes an opening portion 223 and a bulbous portion 228. The term “bulbous” refers to an isolation trench having a bulge. As illustrated in FIG. 2B, the bulge may have sharp corners. However, as illustrated in FIGS. 2C thru 2E the bulge may have rounded corners, for example imitating a bulb. Additionally, the bulge may be located at various different locations along the trench isolation structure 220, including the bottom thereof (e.g., FIGS. 2B thru 2D) or a midpoint thereof (e.g., FIG. 2E), among others.

In the embodiment of FIG. 2B, the bulbous portion 228 is a base portion. In this embodiment, a substantially fixed width (w_{fo}) of the opening portion 223 is less than a substantially fixed width (w_{f1}) of the bulbous portion 228. The phrase “substantially fixed”, as used herein, means that it does not significantly change based upon the location that it is being measured (e.g., within the bulbous portion 228). For ease of understanding, this configuration approximates an inverse T and has substantially vertical sidewalls.

FIG. 2C illustrates a trench isolation structure 230. The trench isolation structure 230 includes an opening portion 233 and a bulbous portion 238. The bulbous portion 238, in this embodiment is again a base portion. In this embodiment, a maximum width (wₘ₀) of the opening portion 233 is less than a maximum width (wₘ₁) of the bulbous portion 238. As the opening portion 233 has substantial vertical sidewalls, the maximum width (wₘ₀) of the opening portion 233 is substantially similar to the opening width (w₀). The embodiment of FIG. 2C is substantially similar to the trench isolation structure 110 illustrated in FIGS. 1A and 1B.

FIG. 2D illustrates a trench isolation structure 240. The trench isolation structure 240 includes an opening portion 243 and a bulbous portion 248. In this embodiment, a maximum width (wₘ₀) of the opening portion 243 is less than a maximum width (wₘ₁) of the bulbous portion 248. However, in this embodiment, a width of the opening portion 243 successively decreases from the opening thereof to the junction with the bulbous portion 248. The bulbous portion 248, in the embodiment of FIG. 2D, is again a base portion.

FIG. 2E illustrates a trench isolation structure 250. The trench isolation structure 250 includes an opening portion 253, a base portion 255 and an interposing bulbous portion 258. In this embodiment, an opening width (w₀) of the opening portion 253 is less than a bulbous width (w_{b1}) of the interposing bulbous portion 258. FIGS. 2A-2E illustrate but a few different embodiments for trench isolation structures manufactured in accordance with the disclosure. Accordingly, other shapes and configurations exist.

FIGS. 3-7 illustrate detailed steps of one example embodiment for manufacturing a trench isolation structure in accordance with this disclosure. FIG. 3 illustrates a trench isolation structure 300 at an initial stage of manufacture. The structure 300 includes a substrate 310. The substrate 310 may, in one embodiment, be any layer located in the structure 300, including a wafer itself or a layer located above the wafer (e.g., epitaxial layer). In the embodiment illustrated in FIG. 3, the substrate 310 is a P-type substrate; however, one skilled in the art understands that the substrate 310 could be an N-type substrate without departing from the disclosure.

Located over the substrate 310 is a patterned hardmask 320 and patterned resist 330. Those skilled in the art understand the process of patterning the hardmask layer 320 and the resist layer 330. The process would generally begin by depositing a conformal layer of masking material over the substrate 310. The layer of masking material, in this embodiment, may comprise an insulative material, such as SiO₂, SiN, or a combination thereof. In one specific embodiment, however, the layer of masking material comprises a first layer of oxide (SiO₂) and a layer of nitride (SiN). However, a second layer of oxide may be used over the nitride layer. As an example, the first oxide layer may have a thickness ranging from about 1.5 nm to about 10 nm, the layer of nitride may have a thickness ranging from about 2.0 nm to about 15 nm, and the optional second layer of oxide may have thickness ranging from about 1.0 nm to about 10 nm. Any suitable Chemical Vapor Deposition (“CVD”) or furnace-based machine may be used to form the layer of masking material.

Thereafter, a radiation sensitive resist coating (e.g., a conformal layer of resist) would be formed over the conformal layer of masking material. The radiation sensitive resist coating would then be patterned by selectively exposing the resist through a mask. In turn, the exposed areas of the coating become either more or less soluble than the unexposed areas, depending on the type of resist. A solvent developer would then be used to remove the less soluble areas leaving the patterned resist layer 330. The patterned resist layer 330, and an appropriate etch, could then be used to pattern the masking layer 320, thus exposing the substrate 310.

The patterned hardmask 320 and/or the patterned resist 330 may then be used to form a first portion 340 of an isolation trench within the substrate 310. The first portion 340, in the embodiment of FIG. 3, may be formed by subjecting the exposed portion of the substrate 310 to an appropriate etch. In one embodiment, the appropriate etch is an anisotropic etch. Because of the anisotropic nature of this etch, the first portion 340 should have substantially vertical sidewalls. In the embodiment shown, the sidewalls have a slight slope to them, however, such a slope is still considered substantially vertical.

It is also within the scope of the disclosure to etch the first portion 340 to any suitable depth. In the example application, the first portion 340 is etched to a depth between about 50 nm and about 150 nm. Nevertheless, this depth is highly dependent on the desires of the manufacturer, and thus other depths could be used.

The anisotropic etch used to form the first portion 340, in one embodiment, leaves a polymer layer 350 on sidewalls of the first portion 340. In the example embodiment, the polymer layer 350 has a greater thickness at the top of the first portion 340 than the bottom of the first portion. Additionally, the polymer layer 350 may extend from about 50 nm to about 100 nm into the first portion 340, among other distances. It is believed that the polymer layer 350 is formed as a result of the etch chemistry (e.g., HBr/O₂ based) used to form the first portion 340.

FIG. 4 illustrates the structure 300 of FIG. 3 after subjecting it to a second etch, thus forming a bulbous portion 410, which in this embodiment is a base portion. Again, the structure 300 uses the patterned hardmask 320 and/or patterned resist 330 to expose portions of the substrate 310 to the second etch. In the example embodiment of FIG. 4, an isotropic etch is used to form the bulbous portion 410. For example, an isotropic chemical based etch (e.g., using SF₆ and O₂) could be used to form the bulbous portion 410. Such an etch chemistry helps to achieve the bulbous shape for the bulbous portion 410. Additionally, the polymer layer 350 may act as an etch stop layer to the isotropic etch. Accordingly, the isotropic etch does not substantially affect the opening portion 340.

One example etch chemistry for the isotropic etch includes using about 3 sccm of SF₆ and about 80 sccm of Ar. Moreover, this example etch might additionally use a 200 watt source, zero bias voltage and about 20 millitorr of pressure. Such example conditions might be used on a LAM etcher, among others. The time for conducting the etch would generally be tailored for a specific depth and/or shape. Other etches (as well as tools) than that disclosed above could also be used.

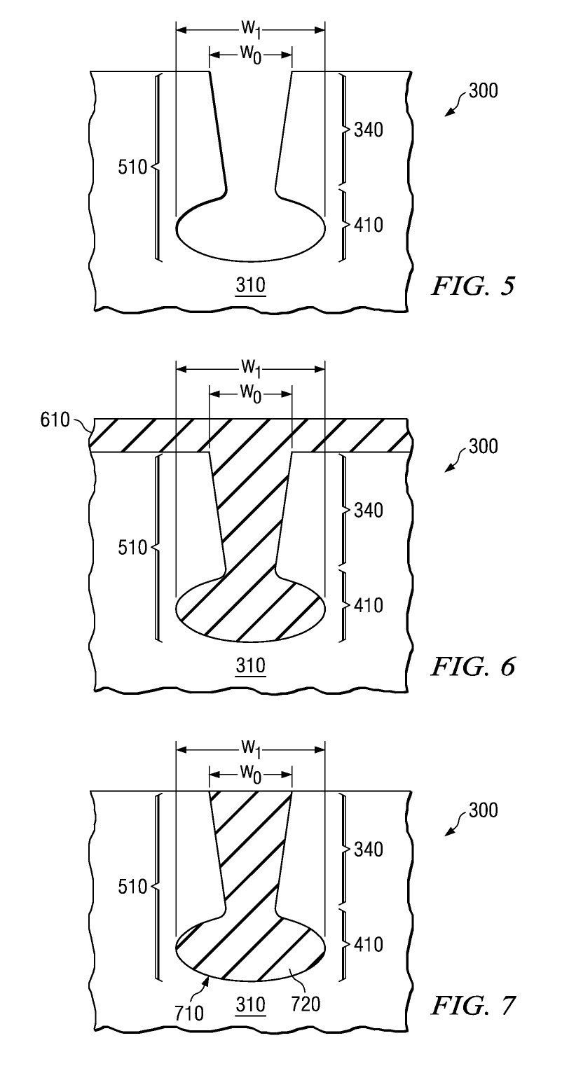

FIG. 5 illustrates the structure 300 of FIG. 4 after removing the patterned resist 330 and patterned hardmask 320. Those skilled in the art understand the process that might be used to remove the patterned resist 330, including using a conventional plasma etch process. Those skilled in the art also understand the myriad of processes that might be used to remove the patterned hardmask 320. For instance, many different processes might be used based on the type of material that the patterned hardmask 320 comprises. In the example embodiment wherein the patterned hardmask 320 comprises a first oxide material and a second nitride material, the second nitride material might be removed using a wet etch (e.g., a phosphoric acid strip) and the first oxide material might be removed using a HF wet etch. If the patterned hardmask 320 were to comprise a different material or materials, another suitable etch would be used.

What results after removal of the patterned resist 330 and patterned hardmask 320 is an isolation trench 510. The isolation trench 510, in this embodiment, includes an opening width (w₀). The isolation trench 510 additionally includes another width (w₁). The other width (w₁), in this embodiment, happens to be the maximum width of the bulbous portion 410. In accordance with this disclosure, the opening width (w₀) is less than the other width (w₁).

FIG. 6 illustrates the structure 300 of FIG. 5 after forming a layer of dielectric material 610 over the substrate 310 and within the isolation trench 510. The layer of dielectric material 610 may comprise many different materials and remain within the purview of the disclosure. For instance, the layer of dielectric material 610 might comprise silicon dioxide in one embodiment. The silicon dioxide would typically be deposited using a Chemical Vapor Deposition (CVD) process. In an alternative embodiment, the layer of dielectric material 610 comprises a spin on type material. For example, the layer of dielectric material 610 could comprise Spin on Glass and/or traditionally deposited oxides such as high density plasma (HDP) oxides and subatomic chemical vapor deposition (SACVD) oxides. This embodiment is particularly useful when the isolation trench 510 is of a size that is difficult to fill using non spin-on processes. Those skilled in the art understand the process conditions that might be used to form the layer of dielectric material 610.

FIG. 7 illustrates the structure 300 of FIG. 6 after subjecting the layer of dielectric material 610 to a chemical mechanical polishing (CMP) process. In the illustrative embodiment, the CMP process removes the layer of dielectric material 610 from above a top surface of the substrate 310. Those skilled in the art understand the process of using CMP to remove the unwanted layer of dielectric material 610. Therefore, no further detail is needed. What results from the CMP process is a trench isolation structure 710 including dielectric material 720 substantially filling the isolation trench 510.

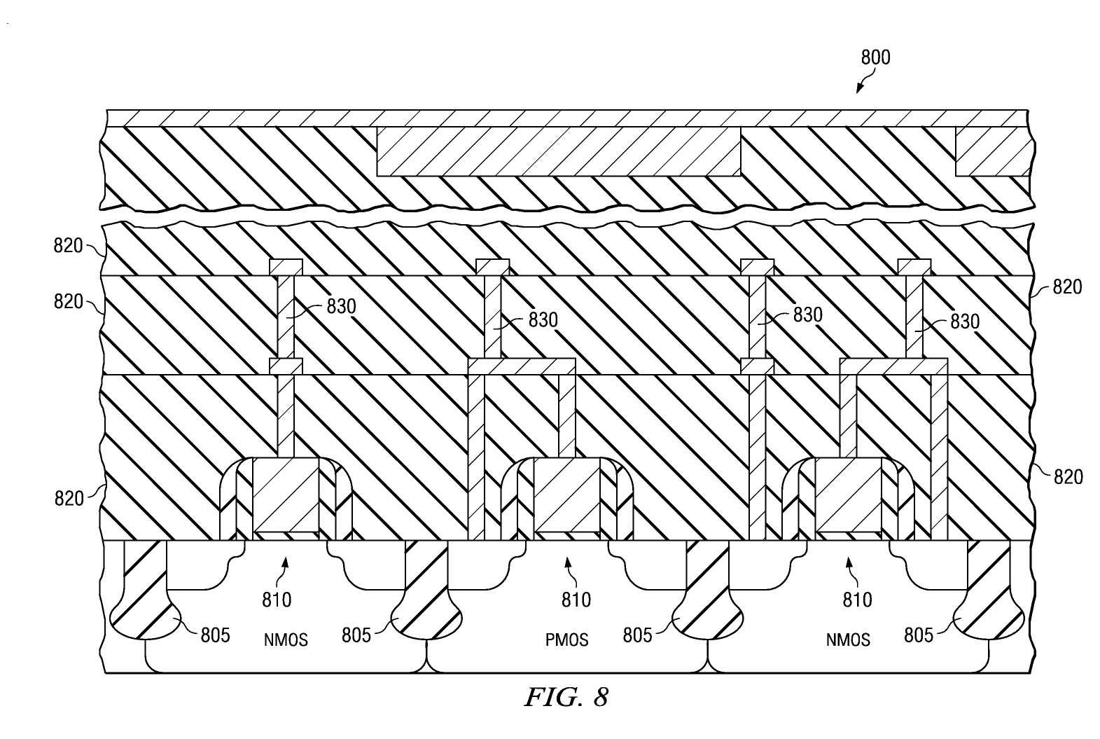

FIG. 8 illustrates an integrated circuit (IC) 800 having been manufactured using one embodiment of the disclosure. The IC 800 may include devices, such as transistors used to form CMOS devices, BiCMOS devices, Bipolar devices, as well as capacitors or other types of devices. The IC 800 may further include passive devices, such as inductors or resistors, or it may also include optical devices or optoelectronic devices. Those skilled in the art are familiar with these various types of devices and their manufacture. In the particular embodiment illustrated in FIG. 8, the IC 800 includes trench isolation structures 805 isolating devices 810. For instance, in one embodiment the trench isolation structures 805 are similar to the trench isolation structures described above with respect to FIGS. 1A-7. Located over the devices 810 are interlevel dielectric layers 820. Located within the interlevel dielectric layers 820 and contacting the devices 810 are interconnects 830. The resulting IC 800 is optimally configured as an operational integrated circuit.

The phrase “providing a substrate”, as used herein, means that the substrate may be obtained from a party having already manufactured it, or alternatively may mean manufacturing the substrate themselves and providing it for its intended purpose.

Those skilled in the art to which the invention relates will appreciate that other and further additions, deletions, substitutions and modifications may be made to the described embodiments without departing from the scope of the invention.

What is claimed is:

1. A semiconductor device, comprising:
a substrate having a first device region and a second device region, wherein the first device region includes a first gate structure and first source/drain regions and the second device region includes a second gate structure and second source/drain regions; and
a trench isolation structure configured to isolate the first device region from the second device region, the trench isolation structure comprising:
an isolation trench located within the substrate, wherein the isolation trench includes an opening portion and a bulbous portion, and further wherein a maximum width of the opening portion is less than a maximum width of the bulbous portion; and
dielectric material substantially filling the isolation trench.

2. The device of claim 1 wherein the bulbous portion has a substantially fixed width, and further wherein the substantially fixed width is greater than the maximum width of the opening portion.

3. The device of claim 1 wherein the bulbous portion is a base portion.

4. The device of claim 3 wherein a width of the opening portion successively decreases as it approaches the base portion.

5. The device of claim 1 further including a base portion, wherein the bulbous portion interposes the opening portion and the base portion.

6. The device of claim 1 further including interlevel dielectric layers located over the first gate structure and the second gate structure, wherein the interlevel dielectric layers include interconnects therein for contacting the first gate structure and the second gate structure.

7. A trench isolation structure, comprising:
an isolation trench located within a substrate, wherein the isolation trench is configured such that a ratio of an opening width of the isolation trench to a base width of the isolation trench is less than about 1:1.1; and
dielectric material substantially filling the isolation trench.

8. The trench isolation structure of claim 7 wherein a width of the isolation trench successively increases from the opening width to the base width.

9. A method for manufacturing a semiconductor device, comprising:
providing a substrate having a first device region and a second device region;
forming a trench isolation structure configured to isolate the first device region from the second device region, including:
forming an isolation trench within the substrate, wherein the isolation trench includes an opening portion and a bulbous portion, and further wherein a maximum width of the opening portion is less than a maximum width of the bulbous portion; and
substantially filling the isolation trench with dielectric material;
forming a first gate structure and first source/drain regions in the first device region; and
forming a second gate structure and second source/drain regions in the second device region.

10. The method of claim 9 wherein the bulbous portion has a substantially fixed width, and further wherein the substantially fixed width is greater than the maximum width of the opening portion.

11. The method of claim 9 wherein the bulbous portion is a base portion.

12. The method of claim 11 wherein a width of the opening portion successively decreases as it approaches the base portion.

13. The method of claim 9 further including a base portion, wherein the bulbous portion interposes the opening portion and the base portion.

14. The method of claim 9 wherein an anisotropic etch is used to form the opening portion and an isotropic etch is used to form the bulbous portion.

15. The method of claim 14 wherein the anisotropic etch causes a polymer layer to form on sidewalls of the opening portion, and further wherein the polymer layer acts as an etch stop layer to the isotropic etch.

16. The method of claim 15 wherein the isotropic etch includes SF₆ and O₂.

17. The method of claim 9 further including forming interlevel dielectric layers over the first gate structure and the second gate structure, wherein the interlevel dielectric layers include interconnects therein for contacting the first gate structure and the second gate structure.

18. A method for manufacturing a trench isolation structure, comprising:
forming an isolation trench within a substrate, wherein the isolation trench is configured such that a ratio of an opening width of the isolation trench to a base width of the isolation trench is less than about 1:1.1; and
substantially filling the isolation trench with dielectric material.

19. The method of claim 18 wherein a width of the isolation trench successively increases from the opening width to the base width.
